(19) United States
(12) Patent Application Publication
(10) Pub. No.: US 2017/0256554 A1
(43) Pub. Date: Sep. 7, 2017

(54) MANUFACTURING METHOD OF NON-VOLATILE SEMICONDUCTOR MEMORY DEVICE AND NON-VOLATILE SEMICONDUCTOR MEMORY DEVICE

(71) Applicant: KABUSHIKI KAISHA TOSHIBA, Tokyo (JP)

(72) Inventor: Hiroaki NAITO, Yokkaichi (JP)

(73) Assignee: KABUSHIKI KAISHA TOSHIBA, Tokyo, (JP)

(21) Appl. No.: 15/242,975

(22) Filed: Aug. 22, 2016

Related U.S. Application Data
(60) Provisional application No. 62/302,264, filed on Mar. 2, 2016.

(51) Int. Cl. H01L 27/115; G11C 16/26; G11C 16/04

(52) U.S. Cl. CPC H01L 27/11524; H01L 27/11529; H01L 27/11531; H01L 27/11556; G11C 16/0408; G11C 16/26

(57) ABSTRACT

According to one embodiment, a conductive layer is patterned based on a first mask pattern to form word lines extending in a cell array region in a row direction, a slit is formed in the conductive layer in a peripheral region to form first air gaps between the word lines, a first insulation film is formed on the conductive layer to cover the slit, the conductive layer is patterned based on a second mask pattern to form select gate lines extending in the cell array region in the row direction, and the conductive layer in the peripheral region is divided in a column direction.

### CROSS-REFERENCE TO RELATED APPLICATIONS

This application is based upon and claims the benefit of priority from U.S. Provisional Application No. 62/302,264, filed on Mar. 2, 2016; the entire contents of which are incorporated herein by reference.

### FIELD

Embodiments described herein relate generally to a manufacturing method of a non-volatile semiconductor memory device and the non-volatile semiconductor memory device.

### BACKGROUND

Non-volatile semiconductor memory devices have had finer memory cells in accordance with increase in memory capacity. With the microfabrication of the memory cells, peripheral circuits for use in reading data from the memory cells are also made finer.

### BRIEF DESCRIPTION OF THE DRAWINGS

FIG. 1 is a plane view illustrating a layout configuration of a non-volatile semiconductor memory device according to a first embodiment;

FIG. 2 is a circuit diagram illustrating a schematic configuration of blocks of the non-volatile semiconductor memory device illustrated in FIG. 1;

FIG. 3A is a plane view illustrating a layout configuration example of the blocks illustrated in FIG. 2, and FIG. 3B is a plane view illustrating a layout configuration example of sense amplifier circuits illustrated in FIG. 1;

FIG. 4A is a perspective view illustrating a schematic configuration of an E1 portion illustrated in FIG. 3A, FIG. 4B is a perspective view illustrating a schematic configuration of an E2 portion illustrated in FIG. 3B, and FIG. 4C is a perspective view illustrating another example of a schematic configuration of the E2 portion illustrated in FIG. 3B;

FIGS. 5A to 5E are plane views illustrating a manufacturing method of a non-volatile semiconductor memory device according to a second embodiment;

FIGS. 6A to 6C are cross-sectional views illustrating the manufacturing method of a non-volatile semiconductor memory device according to the second embodiment;

FIGS. 7A to 7C are cross-sectional views illustrating the manufacturing method of a non-volatile semiconductor memory device according to the second embodiment;

FIGS. 8A to 8C are cross-sectional views illustrating the manufacturing method of a non-volatile semiconductor memory device according to the second embodiment;

FIGS. 9A to 9C are cross-sectional views illustrating the manufacturing method of a non-volatile semiconductor memory device according to the second embodiment;

FIGS. 10A to 10C are cross-sectional views illustrating the manufacturing method of a non-volatile semiconductor memory device according to the second embodiment;

FIGS. 11A to 11C are cross-sectional views illustrating the manufacturing method of a non-volatile semiconductor memory device according to the second embodiment;

FIGS. 12A to 12E are plane views illustrating a manufacturing method of a non-volatile semiconductor memory device according to a third embodiment;

FIGS. 13A to 13E are cross-sectional views illustrating the manufacturing method of a non-volatile semiconductor memory device according to the third embodiment, and FIG. 13F is a plane view illustrating the manufacturing method of a non-volatile semiconductor memory device according to the third embodiment;

FIGS. 14A to 14E are cross-sectional views illustrating a manufacturing method of a non-volatile semiconductor memory device according to a fourth embodiment;

FIGS. 15A to 15E are cross-sectional views illustrating the manufacturing method of a non-volatile semiconductor memory device according to the fourth embodiment;

FIGS. 16A to 16E are cross-sectional views illustrating a manufacturing method of a non-volatile semiconductor memory device according to a fifth embodiment; and

FIGS. 17A to 17E are cross-sectional views illustrating the manufacturing method of a non-volatile semiconductor memory device according to the fifth embodiment.

### DETAILED DESCRIPTION

In general, according to one embodiment, a manufacturing method of a non-volatile semiconductor memory device in which memory cells are arranged in a cell array region in a row direction and a column direction includes: generating a conductive layer in the cell array region and a peripheral region; patterning the conductive layer based on a first mask pattern formed by first lithography to form word lines extending in the cell array region in the row direction and forming a slit in the conductive layer in the peripheral region; forming a first insulation film on the conductive layer to cover the word lines such that a first air gap is generated between the word lines and cover the slit; and patterning the conductive layer based on a second mask pattern formed by second lithography to form select gate lines extending in the cell array region in the row direction, separating the conductive layer in the peripheral region in the column direction, and forming gate electrodes divided by the slit in the row direction in the peripheral region.

Exemplary embodiments of the manufacturing method of a non-volatile semiconductor memory device will be explained below in detail with reference to the accompanying drawings. The present invention is not limited to the following embodiments.

### First Embodiment

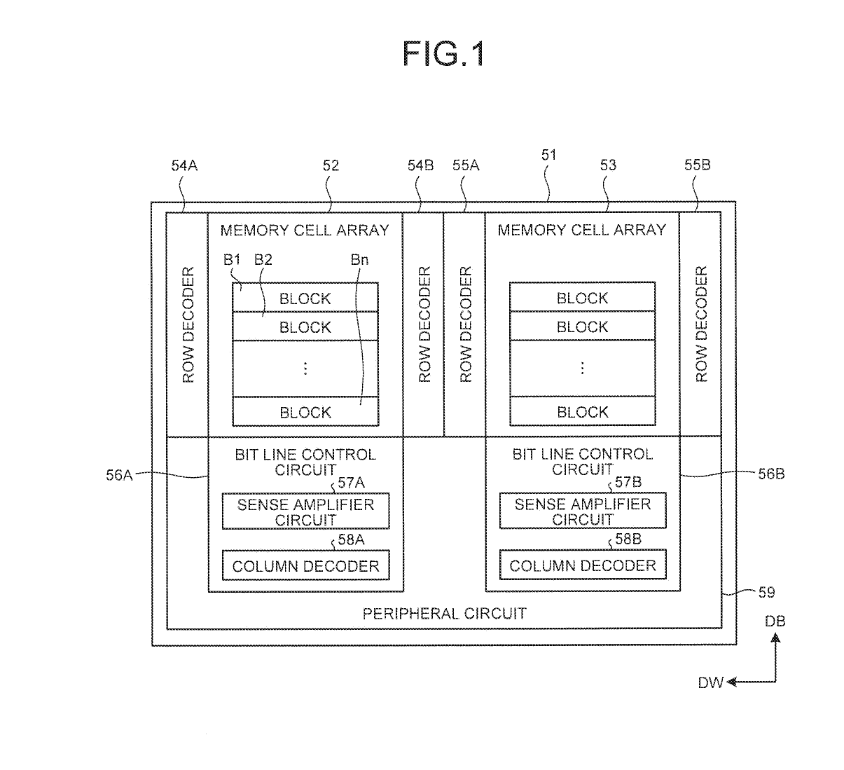

FIG. 1 is a plane view illustrating a layout configuration of a non-volatile semiconductor memory device according to a first embodiment.

Referring to FIG. 1, a semiconductor chip 51 includes memory cell arrays 52 and 53, row decoders 54A, 54B, 55A, and 55B, and a peripheral circuit 59. The peripheral circuit 59 includes the row decoders 54A and 54B and bit line control circuits 56A and 56B. The row decoders 54A and 54B and the bit line control circuit 56A are provided in correspondence with the memory cell array 52, and the row decoders 55A and 55B and the bit line control circuit 56B are provided in correspondence with the memory cell array 53. The bit line control circuits 56A and 56B are provided with sense amplifier circuits 57A and 57B and column decoders 58A and 58B, respectively.

The memory cell arrays 52 and 53 have memory cells storing data and arranged in a matrix in a row direction DW and in a column direction DB. One memory cell may store one bit of data or may be multivalued to store two or more bits of data.

Each of the memory cell arrays 52 and 53 is divided into n (n denotes a positive integer) blocks B1 to Bn. The blocks B1 to Bn can be configured to have a plurality of NAND cell units in the row direction DW.

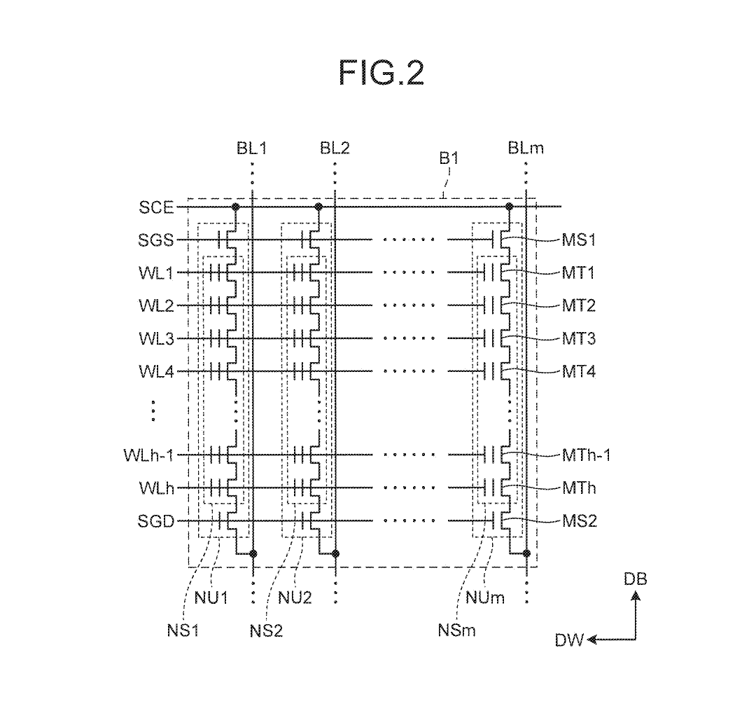

FIG. 2 is a circuit diagram illustrating a schematic configuration of the blocks of the non-volatile semiconductor memory device illustrated in FIG. 1.

Referring to FIG. 2, each of the blocks B1 to Bn illustrated in FIG. 1 includes h (h denotes a positive integer) word lines WL1 to WLh, select gate lines SGD and SGS, and a source line SCE. In addition, the blocks B1 to Bn include m (m denotes a positive integer) bit lines BL1 to BLm in common.

Each of the blocks B1 to Bn includes m NAND cell units NU1 to NUm that are connected to the bit lines BL1 to BLm, respectively.

Each of the NAND cell units NU1 to NUm includes memory cells MT1 to MTh and select transistors MS1 and MS2. The memory cells MT1 to MTh are connected in serial to form NAND strings NS1 to NSm. The select transistors MS1 and MS2 are connected to both ends of the NAND strings NS1 to NSm to form the NAND cell units NU1 to NUm.

In the NAND cell units NU1 to NUm, the word lines WL1 to WLh are connected to control gate electrodes of the memory cells MT1 to MTh. First ends of the NAND strings NS1 to NSm are connected to the bit lines BL1 to BLm, respectively, via the select transistor MS2. Second ends of the NAND strings NS1 to NSm are connected to the source line SCE via the select transistor MS1.

In addition, referring to FIG. 1, the row decoders 54A and 54B can select the memory cells of the memory cell array 52 in the row direction DW for reading, writing, and erasing operations of the memory cells. The row decoders 55A and 55B can select the memory cells of the memory cell array 53 in the row direction DW for reading, writing, and erasing operations of the memory cells.

The bit line control circuit 56A can perform a bit line control of the memory cell array 52. The bit line control circuit 56B can perform a bit line control of the memory cell array 53. The column decoder 58A can select the memory cells of the memory cell array 52 in the column direction DB for reading, writing, and erasing operations of the memory cells. The column decoder 58B can select the memory cells of the memory cell array 53 in the column direction DB for reading, writing, and erasing operations of the memory cells.

The sense amplifier circuit 57A can identify the values stored in the memory cells based on the potentials of the bit lines BL1 to BLm of the memory cell array 52, and control the potentials of the bit lines BL1 to BLm according to written data. The sense amplifier circuit 57B can identify the values stored in the memory cells based on the potentials of the bit lines BL1 to BLm of the memory cell array 53, and control the potentials of the bit lines BL1 to BLm according to written data.

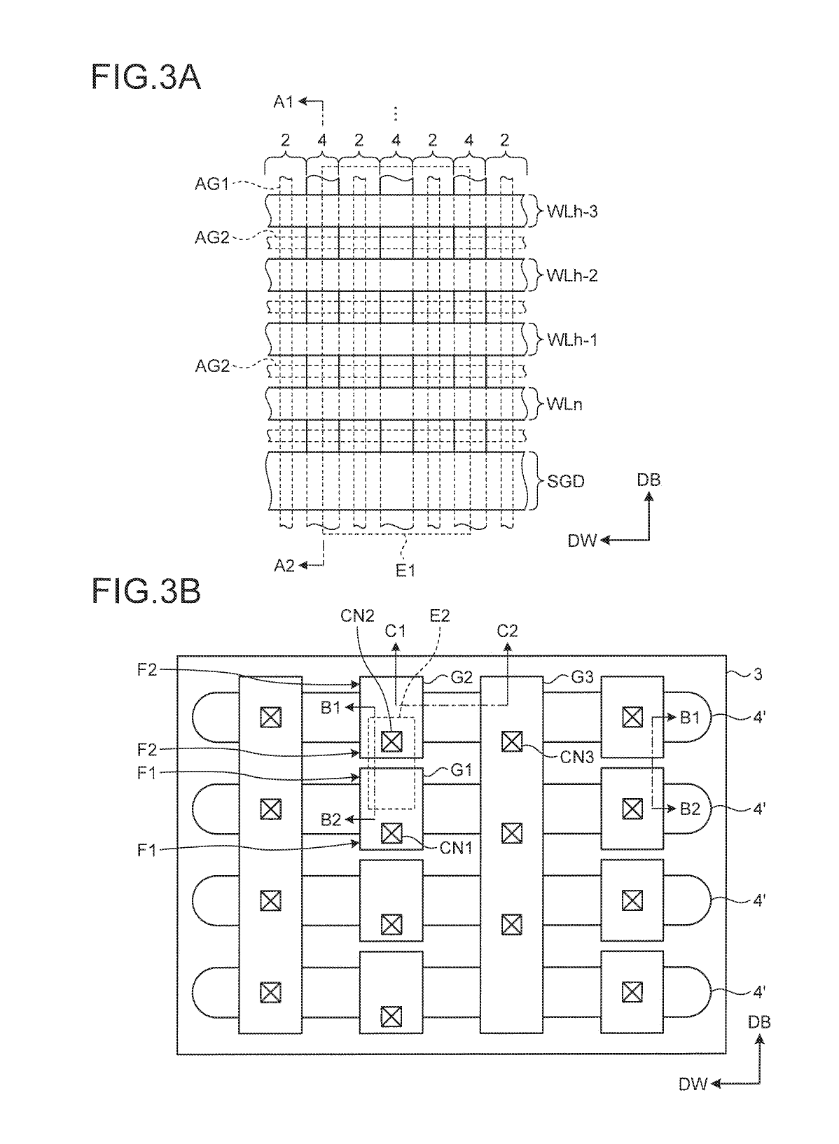

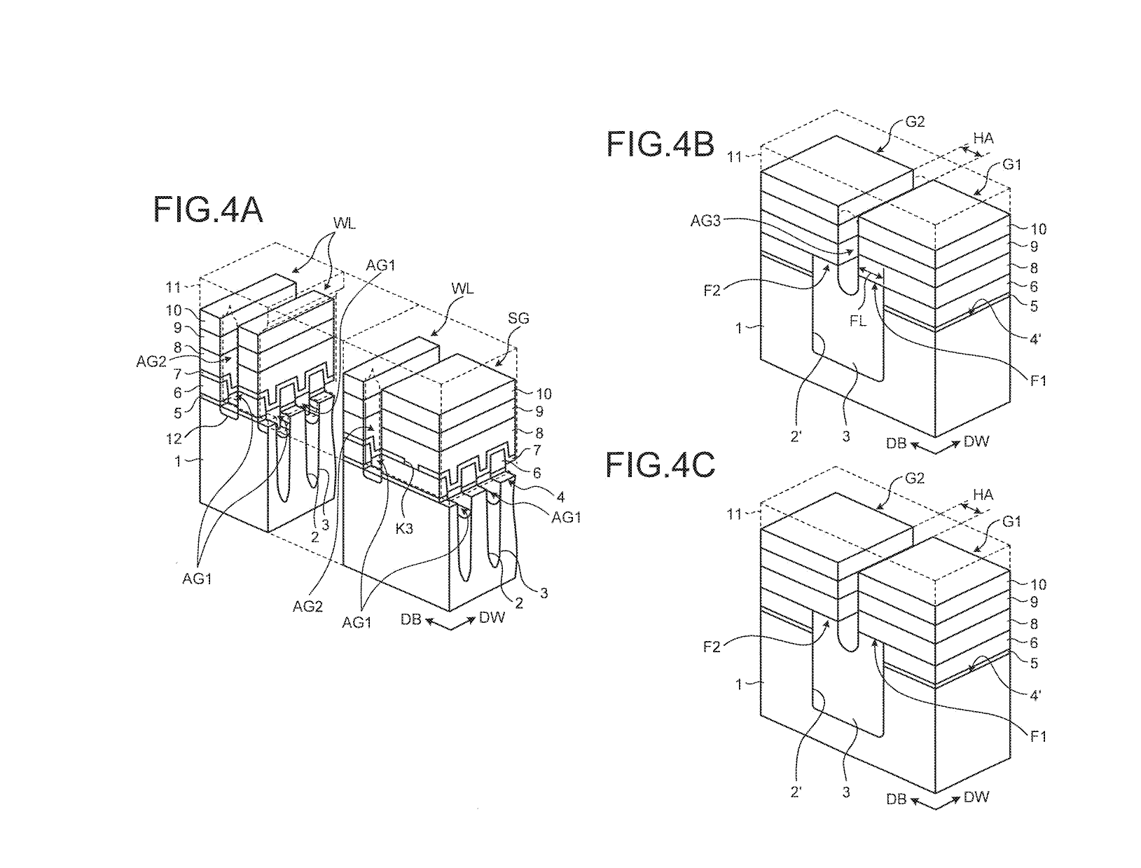

FIG. 3A is a plane view illustrating a layout configuration example of the blocks illustrated in FIG. 2. FIG. 3B is a plane view illustrating a layout configuration example of the sense amplifier circuits illustrated in FIG. 1. FIG. 4A is a perspective view illustrating a schematic configuration of an E1 portion illustrated in FIG. 3A. FIG. 4B is a perspective view illustrating a schematic configuration of an E2 portion illustrated in FIG. 3B. FIG. 4C is a perspective view illustrating another example of a schematic configuration of the E2 portion illustrated in FIG. 3B. The pitch of the bit lines BL1 to BLm connected to the sense amplifier circuit can be set to 15 nm or less.

Referring to FIGS. 3A and 4A, a semiconductor substrate 1 has a plurality of trenches 2 extending in the column direction DB arranged in the row direction DW. The material for the semiconductor substrate 1 can be selected from among Si, Ge, SiGe, SiC, SiSn, PbS, GaAs, InP, GaP, GaN, GaInAsP, and ZnSe, for example. The trenches 2 divide in the row direction DW an active region 4 extending in the column direction DB. The active region 4 can be provided with memory cells and select transistors.

Word lines WL (word lines WL1 to WLh illustrated in FIG. 2) extending in the row direction DW are provided on the trenches 2 and the active region 4. Select gate lines SG (the select gate lines SGD and SGS illustrated in FIG. 2) extending in the row direction DW are provided on the trenches 2 and the active region 4 in parallel to the word lines WL.

An insulation film 3 is continuously embedded in the trenches 2 in the column direction DB. The insulation film 3 can be a silicon dioxide film, for example. As the silicon dioxide film, NSG (non-doped silicate glass) can be used, for example. Air gaps AG1 are provided along the trenches 2 on the insulation film 3.

A floating gate electrode 6 is formed for respective memory cells and select transistors via a tunnel insulation film 5 in the active region 4. The floating gate electrode 6 may be a polysilicon in which N-type impurities or P-type impurities are doped or a metal film or a polymetal film using Mo, Ti, W, Al, or Ta, for example. The tunnel insulation film 5 may be a thermally oxidized film or a thermally oxynitrided film, for example. Otherwise, the tunnel insulation film 5 may be a CVD dioxide film or a CVD oxynitride film.

A control gate electrode 8 is formed in the row direction DW on the floating gate electrode 6 of the memory cells and the select transistors via an inter-electrode insulation film 7. In the memory cells, the control gate electrode 8 can be used for the word lines WL. In the select transistors, the control gate electrode 8 can be used for the select gate lines SG. In this example, an opening K3 is formed in the inter-electrode insulation film 7 on the floating gate electrode 6 of the select transistors. The floating gate electrode 6 is connected to the control gate electrode 8 via the opening K3.

The control gate electrode 8 can be extended on the active region 4 across the trenches 2 via the air gaps AG1. The inter-electrode insulation film 7 can be a silicon dioxide film or a silicon nitride film, for example. Otherwise, the inter-electrode insulation film 7 can have a stacked structure of a silicon dioxide film and a silicon nitride film such as an ONO film.

Otherwise, the inter-electrode insulation film 7 can be a high-dielectric film of aluminum oxide or hafnium oxide, or can have a stacked structure of a low-dielectric film and a high-dielectric film such as a silicon dioxide film or a silicon nitride film. The control gate electrode 8 can be a polysilicon in which N-type impurities or P-type impurities are doped. Otherwise, the control gate electrode 8 can be a metal film or a polymetal film using Mo, Ti, W, Al, or Ta. A cap insulation film 9 is provided on the control gate electrode 8. The material for the cap insulation film 9 can be a silicon nitride film, for example. A hard mask layer 10 is provided on the cap insulation film 9. The material for the hard mask layer 10 can be a silicon dioxide film, for example.

Air gaps AG2 extending in the row direction DW are provided between the word lines WL and between the word line WL and the select gate line SG. A cover insulation film 11 is continuously provided on the hard mask layer 10 in the column direction DB in contact with the upper ends of the air gaps AG2. The material for the cover insulation film 11 can be a silicon dioxide film, for example.

An impurity diffused layer 12 is formed in the active region 4 of the semiconductor substrate 1 between the word lines WL and between the word line WL and the select gate line SG.

Referring to FIGS. 3B and 4B, trenches 2′ are arranged on the semiconductor substrate 1. The trenches 2′ divide an active area 4′ in the row direction DW and in the column direction DB. A gate electrode of a transistor, a source layer, and a drain layer can be provided in the active area 4′. The insulation film 3 is embedded in the trenches 2′.

Gate electrodes G1 to G3 are provided on the trenches 2′ and the active region 4′. The gate electrodes G1 and G2 are separated in the column direction DB. The gate electrode G3 is continuous in the column direction DB across a plurality of active regions 4′. Each of the gate electrodes G1 and G2 includes fringe portions F1 and F2. The fringe portions F1 and F2 extend over the insulation film 3 in the column direction DB. Contacts CN1 to CN3 are provided on the gate electrodes G1 to G3. The contacts CN1 and CN2 can extend over the fringe portions F1 and F2.

The gate electrodes G1 to G3 can have a stacked structure of the tunnel insulation film 5, the floating gate electrode 6, the control gate electrode 8, the cap insulation film 9, and the hard mask layer 10. The structure of the gate electrodes G1 to G3 is the same as the structure in which the inter-electrode insulation film 7 is removed from the word lines WL.

The tunnel insulation film 5 and the floating gate electrode 6 can have edges aligned with the trenches 2′. The control gate electrode 8, the cap insulation film 9, and the hard mask layer 10 can extend over the trenches 2′. When the control gate electrode 8, the cap insulation film 9, and the hard mask layer 10 extend over the trenches 2′, the fringe portions F1 and F2 can be formed.

An air gap AG3 is provided between the gate electrodes G1 and G2. The cover insulation film 11 is provided on the hard mask layer 10 in contact with the upper end of the air gap AG3. The cover insulation film 11 can cover the space between the gate electrodes G1 and G2. The air gap AG3 may eat into the insulation film 3.

FIG. 4B illustrates the case where the air gap AG3 exists between the gate electrodes G1 and G2 under the cover insulation film 11. Alternatively, as illustrated in FIG. 4C, the cover insulation film 11 may fill completely the space between the gate electrodes G1 and G2 to eliminate the need for the air gap AG3 between the gate electrodes G1 and G2 under the cover insulation film 11. The need for the air gap AG3 can depend on an interval HA. When the interval HA is small (for example, 40 nm or less), the air gap AG3 can be provided, and when the interval HA is large (for example, 80 nm or more), the air gap AG3 can be eliminated.

By covering the space between the gate electrodes G1 and G2 by the cover insulation film 11, it is possible to make impurities less prone to enter the active region 4′ at the formation of the impurity diffused layer 12 in the active region 4. This eliminates the need for increasing fringe length FL of the fringe portions F1 and F2, thereby to reduce the layout area of the peripheral circuit 59.

### Second Embodiment

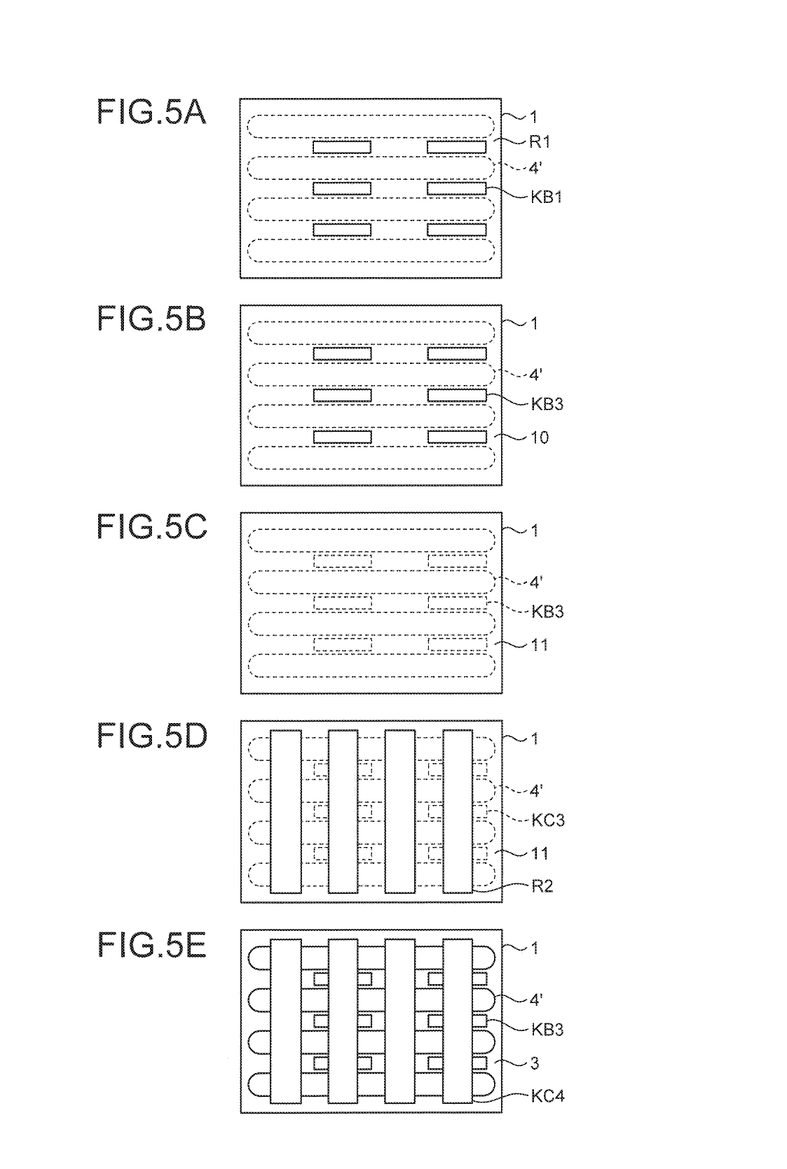

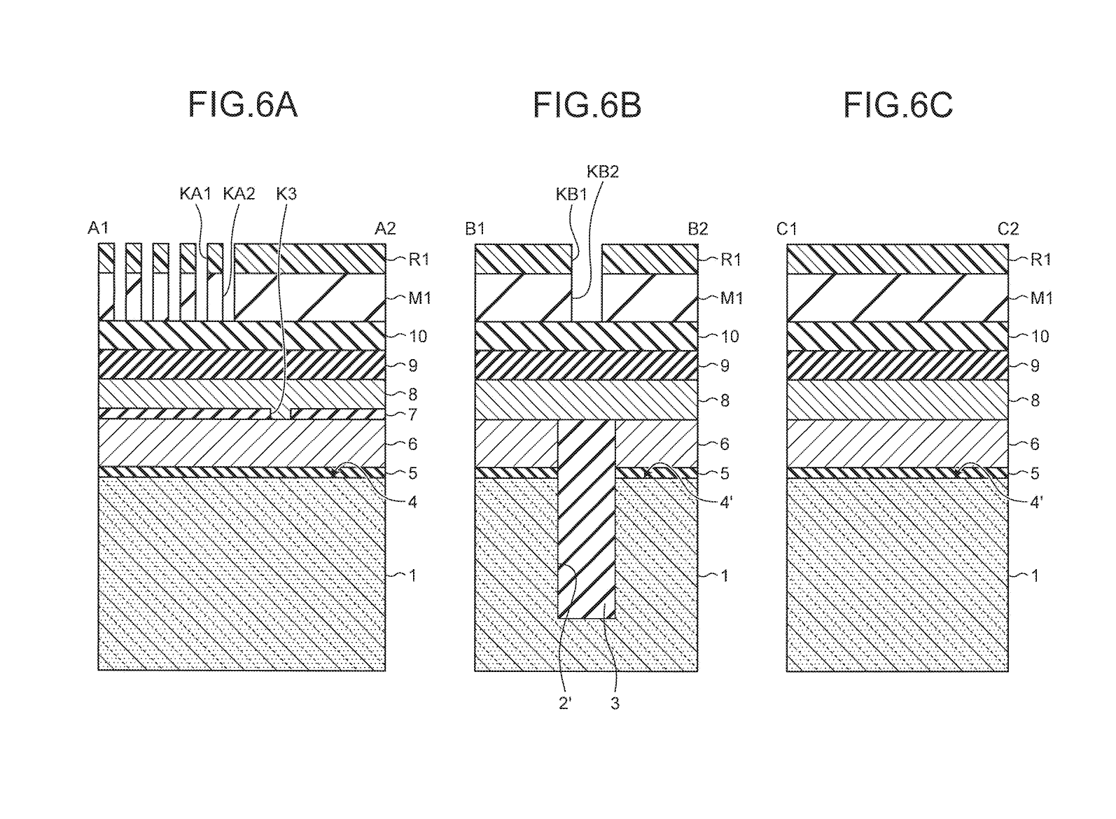

FIGS. 5A to 5E are plane views illustrating a manufacturing method of a non-volatile semiconductor memory device according to a second embodiment. FIGS. 6A to 6C, 7A to 7C, 8A to 8C, 9A to 9C, 10A to 10C, and 11A to 11C are cross-sectional views illustrating the manufacturing method of a non-volatile semiconductor memory device according to the second embodiment. FIGS. 5A to 5E are plane views illustrating the manufacturing method of the configuration illustrated in FIG. 3B. FIGS. 6A to 11A are cross-sectional views illustrating the manufacturing method with the cross section of FIG. 3A taken along line A1-A2. FIGS. 6B to 11B are cross-sectional views illustrating a manufacturing method with the cross section of FIG. 3B taken along line B1-B2. FIGS. 6C to 11C are cross-sectional views illustrating the manufacturing method with the cross section of FIG. 3B taken along line C1-C2.

Referring to FIG. 6A, the tunnel insulation film 5, the floating gate electrode 6, the inter-electrode insulation film 7, the control gate electrode 8, the cap insulation film 9, and the hard mask layer 10 are formed on the active region 4 of the memory cell arrays 52 and 53 illustrated in FIG. 1. The opening K3 is formed in the inter-electrode insulation film 7 on the formation region of the select gate lines SG.

Referring to FIGS. 5A, 6B, and 6C, the tunnel insulation film 5, the floating gate electrode 6, the control gate electrode 8, the cap insulation film 9, and the hard mask layer 10 are formed on the trenches 2′ and the active region 4′ of the sense amplifier circuits 57A and 57B illustrated in FIG. 1. The inter-electrode insulation film 7 is removed from the formation region of the sense amplifier circuits 57A and 57B illustrated in FIG. 1.

The insulation film 3 is embedded in the trenches 2′. By forming the trenches 2′ after the formation of the tunnel insulation film 5 and the floating gate electrode 6 on the semiconductor substrate 1, the tunnel insulation film 5 and the floating gate electrode 6 can be divided by the trenches 2′. In addition, by forming the trenches 2 at the time of formation of the trenches 2′, the active region 4, the tunnel insulation film 5, and the floating gate electrode 6 can be divided by the trenches 2.

Next, a hard mask layer M1 and a resist film R1 are formed on the hard mask layer 10. The material for the hard mask layer M1 can be amorphous silicon, for example. Then, openings KA1 and KB1 are formed in the resist film R1 by a photolithography technique. The hard mask layer M1 is etched via the openings KA1 and KB1 to form openings KA2 and KB2 in the hard mask layer M.

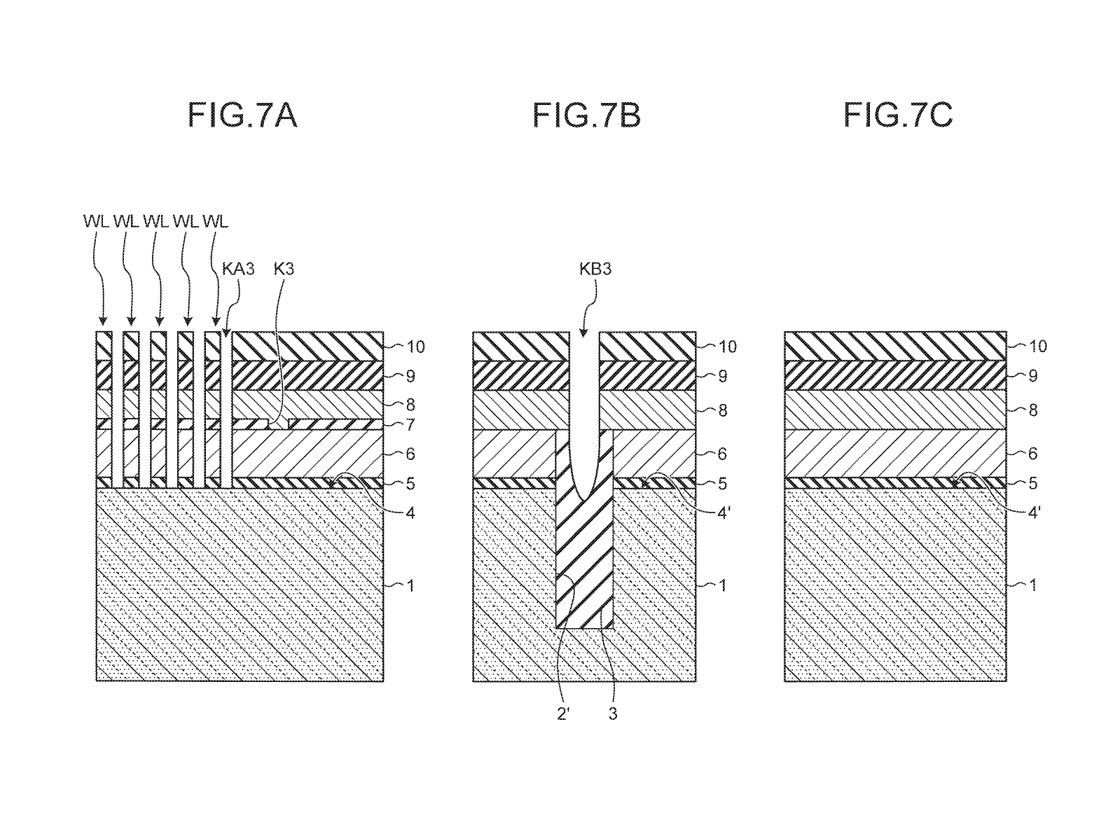

Next, as illustrated in FIGS. 5B and 7A to 7C, the tunnel insulation film 5, the floating gate electrode 6, the control gate electrode 8, the cap insulation film 9, and the hard mask layer 10 are etched via the openings KA2 and KB2 to form an opening KA3 in the tunnel insulation film 5, the floating gate electrode 6, the inter-electrode insulation film 7, the control gate electrode 8, the cap insulation film 9, and the hard mask layer 10 on the trenches 2 and the active region 4, form the word lines WL, and form a slit KB3 in the control gate electrode 8, the cap insulation film 9, and the hard mask layer 10 on the trenches 2′ and the active region 4′. The slit KB3 may eat into the insulation film 3. The slit KB3 can be used to divide the gate electrodes G1 and G2 in the row direction DW.

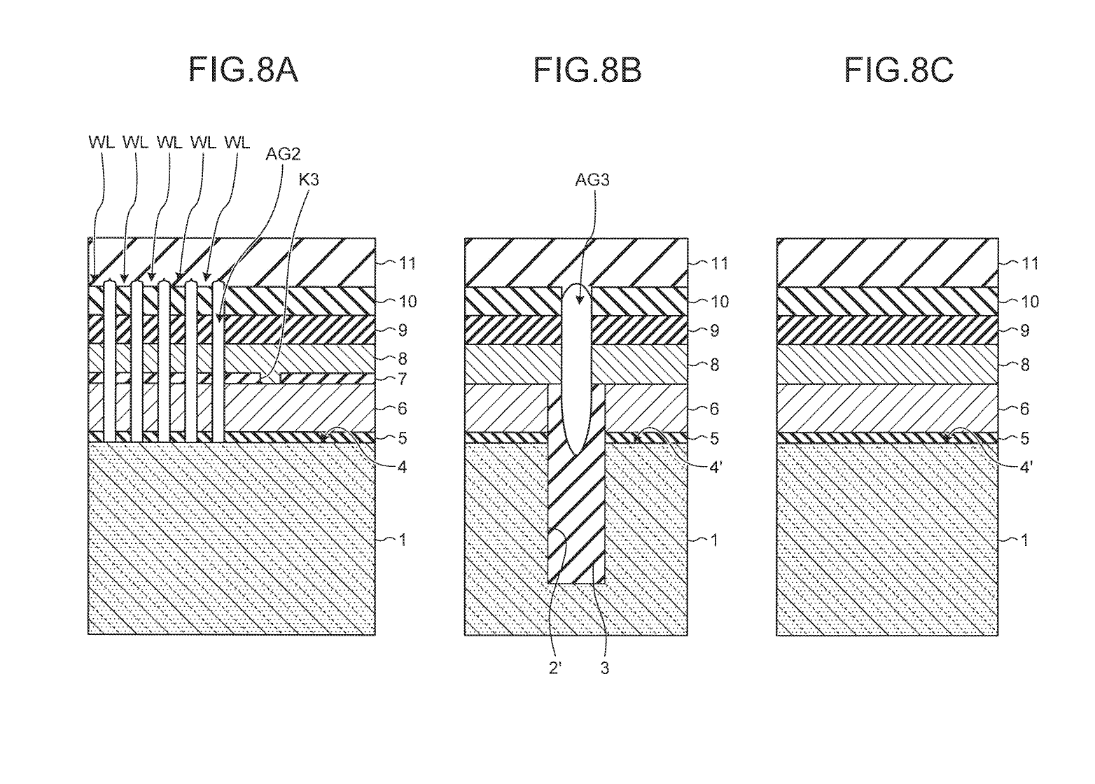

Next, as illustrated in FIGS. 5C and 8A to 8C, the cover insulation film 11 is formed on the hard mask layer 10 by a method such as CVD. At that time, the air gaps AG2 can be formed between the word lines WL and between the word line WL and the select gate line SG. In addition, the air gap AG3 can be formed in the slit KB3. Film forming conditions with poor coverage can be set to prevent the air gaps AG2 from being filled with the cover insulation film 11. As illustrated in FIG. 4C, the slit KB3 may be fully filled with the cover insulation film 11. Otherwise, part of the slit KB3 may be filled with the cover insulation film 11.

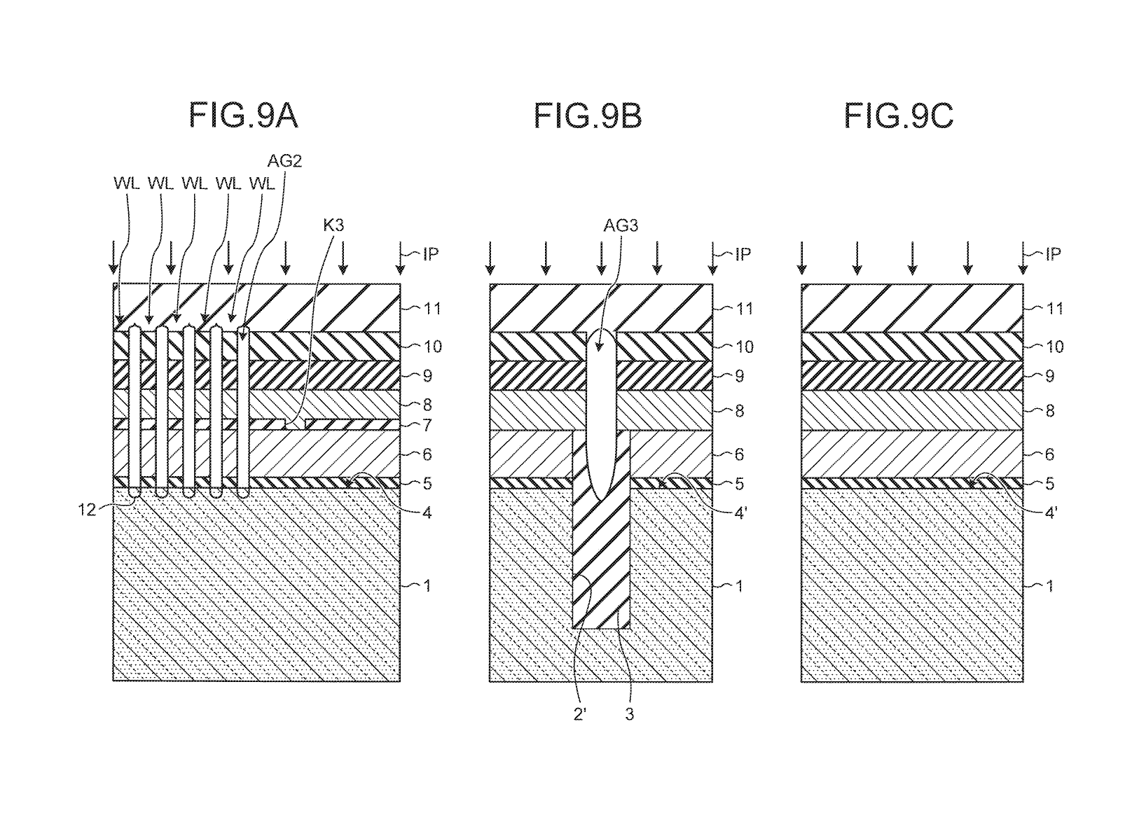

Next, as illustrated in FIGS. 9A to 9C, ion injection IP is performed in the semiconductor substrate 1 via the cover insulation film 11 to form the impurity diffused layer 12 in the active region 4 between the word lines WL and between the word line WL and the select gate line SG.

By covering the slit KB3 with the cover insulation film 11, it is possible to make impurities less prone to enter the active region 4′ and suppress fluctuations in the characteristics of the transistors of the sense amplifier circuits 57A and 57B.

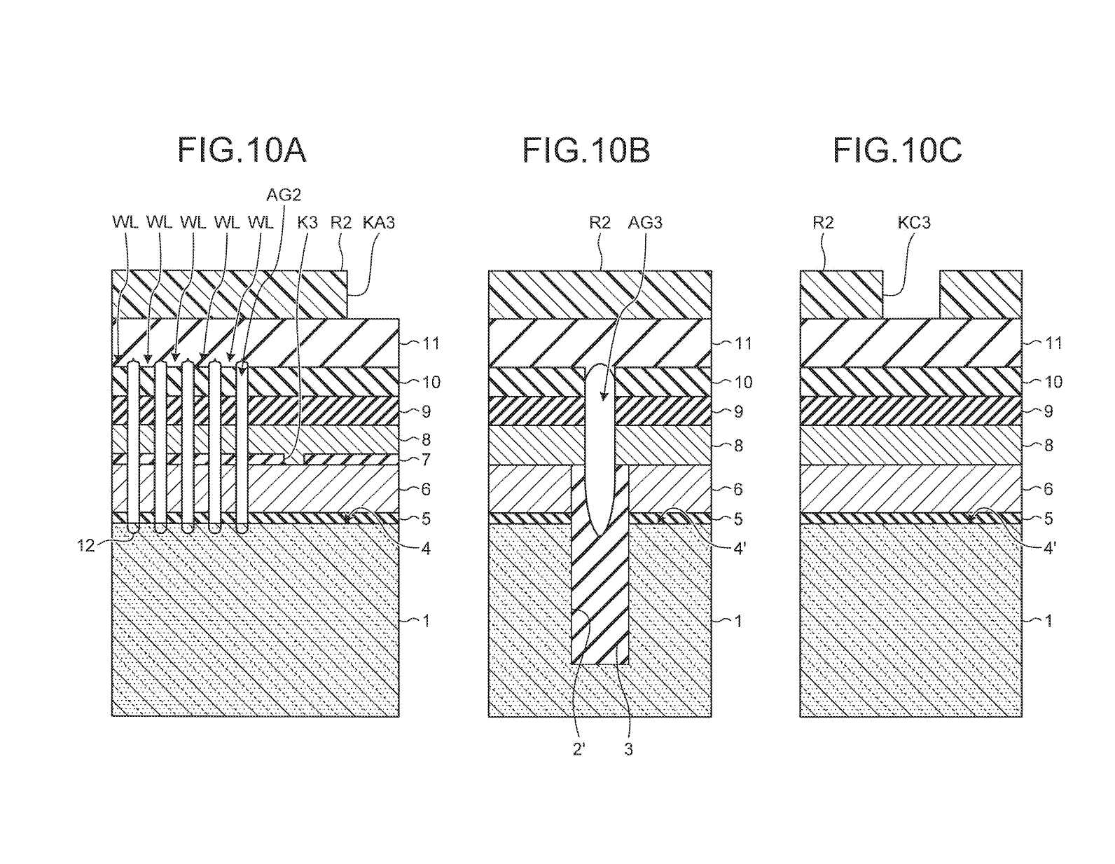

Next, as illustrated in FIGS. 5D and 10A to 10C, a resist film R2 is formed on the cover insulation film 11. Then, openings KA3 and KC3 are formed in the resist film R2 by a photolithography technique.

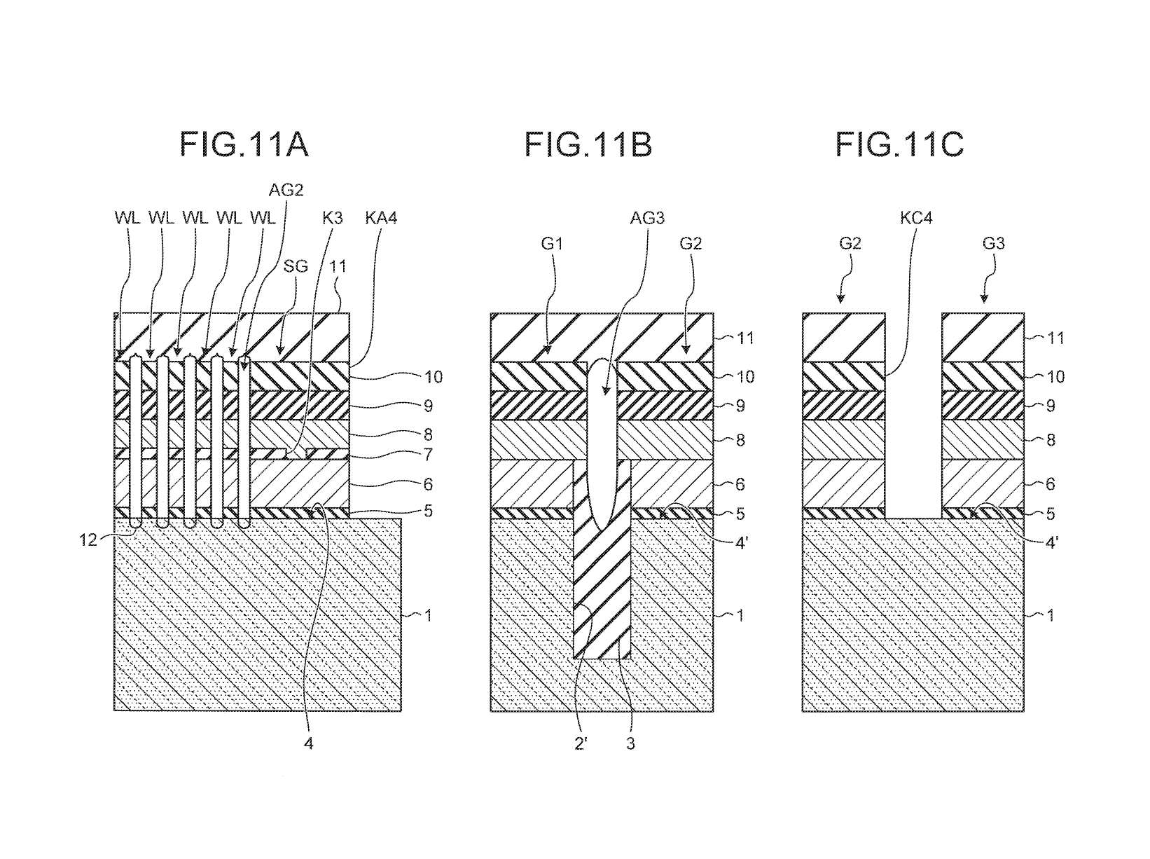

Next, as illustrated in FIGS. 5E and 11A to 11C, the tunnel insulation film 5, the floating gate electrode 6, the control gate electrode 8, the cap insulation film 9, the hard mask layer 10, and the cover insulation film 11 are etched via the openings KA3 and KC3 to form an opening KA4 in the tunnel insulation film 5, the floating gate electrode 6, the inter-electrode insulation film 7, the control gate electrode 8, the cap insulation film 9, the hard mask layer 10, and the cover insulation film 11 on the trenches 2 and the active region 4, form the select gate line SG, form an opening KC4 in the tunnel insulation film 5, the floating gate electrode 6, the control gate electrode 8, the cap insulation film 9, the hard mask layer 10, and the cover insulation film 11 on the trenches 2′ and the active region 4′, and form gate electrodes G1, G2, and G3. The opening KC4 can be used to divide the gate electrodes G1, G2, and G3 in the column direction DB.

### Third Embodiment

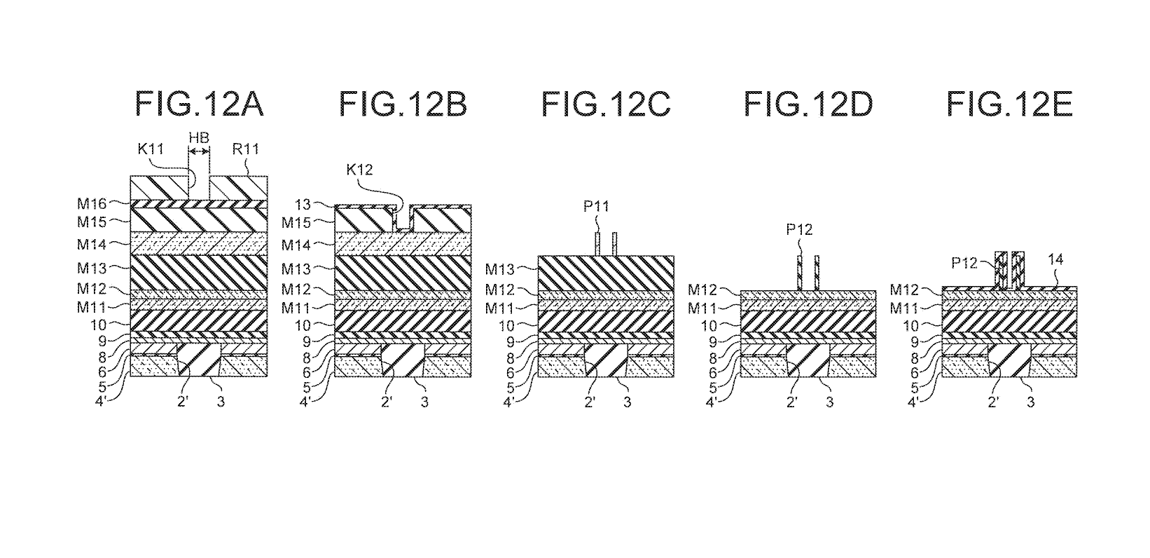

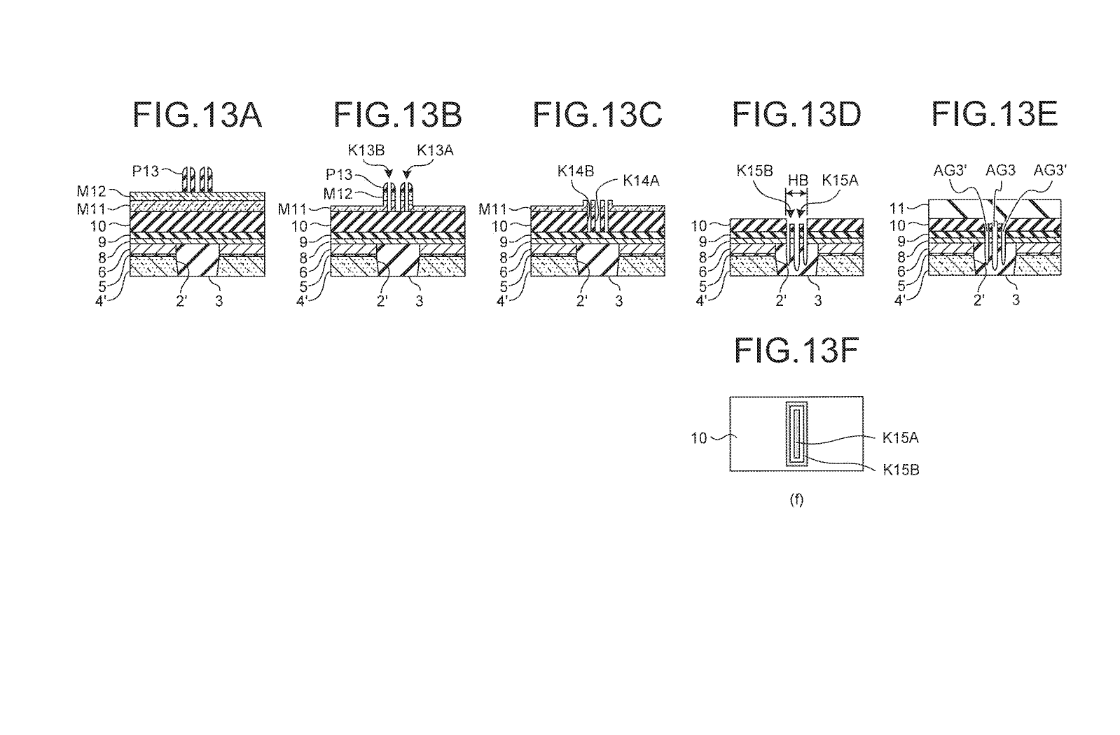

FIGS. 12A to 12E and 13A to 13E are cross-sectional views illustrating a manufacturing method of a non-volatile semiconductor memory device according to a third embodiment, and FIG. 13F is a plane view illustrating the manufacturing method of a non-volatile semiconductor memory device according to the third embodiment. In the third embodiment, the steps illustrated in FIGS. 5A to 5C are implemented using a side wall forming process. By using the side wall forming process, it is possible to set the pitch of the bit lines BL1 to BLm connected to the sense amplifier circuits to 15 nm or less. In the following embodiment, the gate electrodes of the sense amplifier circuits are formed using the side wall forming process.

Referring to FIG. 12A, the tunnel insulation film 5, the floating gate electrode 6, the control gate electrode 8, the cap insulation film 9, and the hard mask layer 10 are formed on the trenches 2′ and the active region 4′.

Next, hard mask layers M11 and M12, a core material layer M13, and hard mask layers M14 to M16 are formed on the hard mask layer 10. The material for the hard mask layers M11, M12, and M14 can be amorphous silicon, for example. The material for the core material layer M13 can be a silicon dioxide film, for example. The material for the hard mask layer M15 can be SOC (Spin On Carbon), for example. The material for the hard mask layer M16 can be SOG (Spin On Glass), for example. Next, a resist film R11 is formed on the hard mask layer M16. Then, an opening K11 is formed in the resist film R11 by a photolithography technique. Width HB of the opening K11 can be set to 100 nm, for example.

Next, as illustrated in FIG. 12B, the hard mask layers M16 and M15 are sequentially etched via the opening K11 to form an opening K12 in the hard mask layer M15. The hard mask layer M16 is removed and then a spacer film 13 is formed on the hard mask layer M15 by a method such as CVD to cover the side walls of the opening K12. The material for the spacer film 13 can be a silicon dioxide film, for example. The film thickness of the spacer film 13 can be set to 15 nm, for example.

Next, as illustrated in FIG. 12C, the spacer film 13 and the hard mask layers M15 and M14 are sequentially etched by a method such as RIE (Reactive Ion Etching) until the core material layer M13 is exposed to form a mask pattern P11 on the core material layer M13. At that time, the etching rate of the spacer film 13 can be lower than that of the hard mask layer M15. The film thickness of the spacer film 13 can be smaller than that of the hard mask layer M15. Accordingly, when the hard mask layer M15 is removed from the hard mask layer M14, the spacer film 13 can be left along the outline of the opening K12. This allows the mask pattern P11 to be arranged on the core material layer M13 along the outline of the opening K12. The width of the mask pattern P11 can be equal to the film thickness of the spacer film 13.

Next, as illustrated in FIG. 12D, the core material layer M13 is etched by a method such as RIE via the mask pattern P11 until the hard mask layer M12 is exposed to form a core material pattern P12 on the hard mask layer M12.

Next, as illustrated in FIG. 12E, a side wall layer 14 is formed on the hard mask layer M12 by a method such as CVD to cover the side walls of the core material pattern P12. The material for the side wall layer 14 can be a silicon nitride film, for example. Before the formation of the side wall layer 14, the core material pattern P12 may be slimmed and thinned.

Next, as illustrated in FIG. 13A, the side wall layer 14 is thinned by a method such as RIE until the hard mask layer M12 is exposed to form side wall patterns P13 on the side walls of the core material pattern P12. Then, the core material pattern P12 is removed from the hard mask layer M12.

Next, as illustrated in FIG. 13B, the hard mask layers M12 and M11 are sequentially etched by a method such as RIE via the side wall patterns P13 to form openings K13A and K13B in the hard mask layers M12 and M11. At that time, an etching condition can be set to obtain an inverse loading effect. Accordingly, the hard mask layer M11 is removed from narrow space between the side wall patterns P13 to form openings K13A and K13B, whereas the hard mask layer M11 can be left on the hard mask layer 10 in a wide region around the side wall patterns P13.

Next, as illustrated in FIG. 13C, the hard mask layer 10 is etched by a method such as RIE via the openings K13A and K13B to form openings K14A and K14B in the hard mask layer 10.

Next, as illustrated in FIG. 13D, the cap insulation film 9 and the control gate electrode 8 are sequentially etched by a method such as RIE via the openings K14A and K14B to form openings K15A and K15B in the cap insulation film 9 and the control gate electrode 8. At that time, as illustrated in FIG. 13F, the opening K15B can surround the opening K15A. The opening K15A can be used as the slit KB3 illustrated in FIG. 7B.

Next, as illustrated in FIG. 13E, the cover insulation film 11 is formed on the hard mask layer 10 by a method such as CVD. At that time, the air gap AG3 can be formed in the opening K15A, and an air gap AG3′ can be formed in the opening K15B.

### Fourth Embodiment

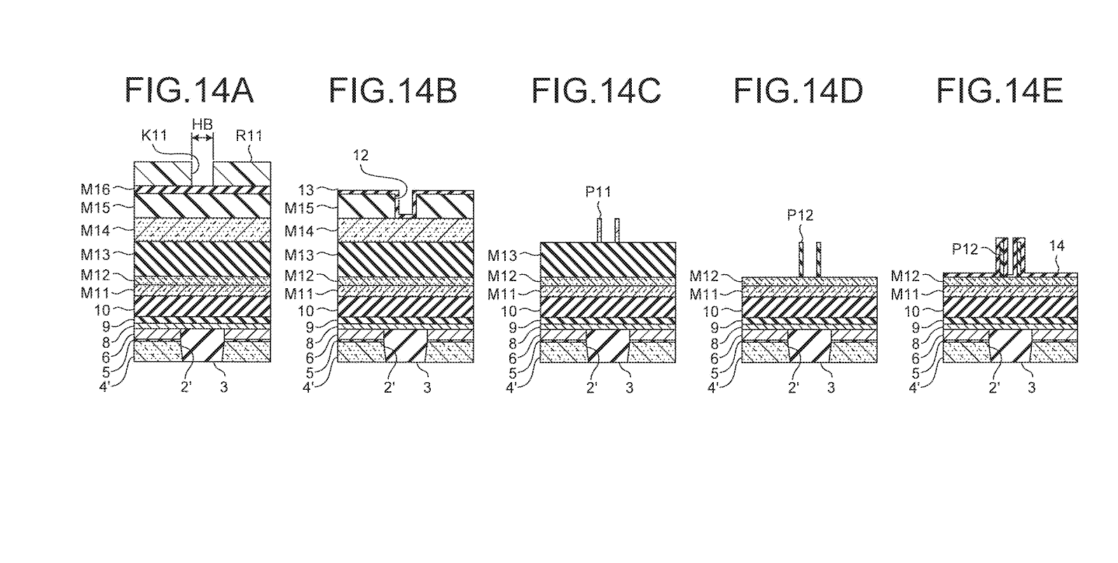

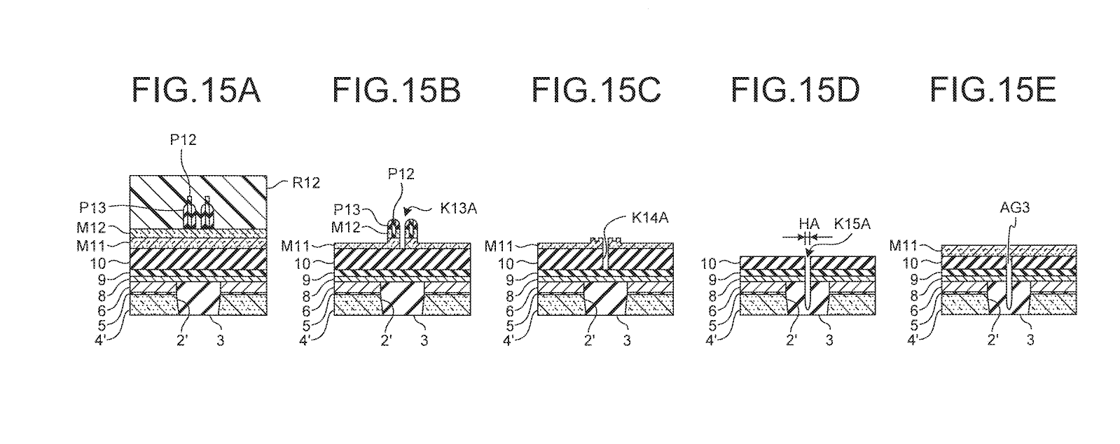

FIGS. 14A to 14E and 15A to 15E are cross-sectional views illustrating a manufacturing method of a non-volatile semiconductor memory device according to a fourth embodiment. In the fourth embodiment, the steps illustrated in FIGS. 5A to 5C are implemented using the side wall forming process as another example. The fourth embodiment is configured such that the opening K15B is not formed at the time of formation of the opening K15A illustrated in FIG. 13D.

The steps illustrated in FIGS. 14A to 14E are the same as the steps illustrated in FIGS. 12A to 12E.

Next, as illustrated in FIG. 15A, the side wall layer 14 is thinned by a method such as RIE until the hard mask layer M12 is exposed to form a side wall patterns P13 on the side walls of the core material pattern P12. Then, a resist pattern R12 is formed on the hard mask layer M12 with the trenches 2′ and the active region 4′, without removing the core material pattern P12 from the hard mask layer M12.

At that time, the resist pattern R12 can be removed from the hard mask layer M12 with the trenches 2 and the active region 4. Then, the core material pattern P12 is etched via the resist pattern R12 to remove the core material pattern P12 from the hard mask layer M12 with the trenches 2 and the active region 4 and leave the core material pattern P12 on the hard mask layer M12 with the trenches 2′ and the active region 4′.

Next, as illustrated in FIG. 15B, the resist pattern R12 is removed from the hard mask layer M12. Then, the hard mask layers M12 and M11 are sequentially etched by a method such as RIE via the side wall patterns P13 and the core material pattern P12 to form an opening K13A in the hard mask layers M12 and M11.

At that time, an etching condition can be set to obtain an inverse loading effect. Accordingly, the hard mask layer M11 is removed from narrow space between the side wall patterns P13 to form the opening K13A, whereas the hard mask layer M11 can be left on the hard mask layer 10 in a wide region around the side wall patterns P13 and the core material pattern P12.

Next, as illustrated in FIG. 15C, the hard mask layer 10 is etched by a method such as RIE via the opening K13A to form the opening K14A in the hard mask layer 10.

Next, as illustrated in FIG. 15D, the cap insulation film 9 and the control gate electrode 8 are sequentially etched by a method such as RIE via the opening K14A to form the opening K15A in the cap insulation film 9 and the control gate electrode 8.

Next, as illustrated in FIG. 15E, the cover insulation film 11 is formed on the hard mask layer 10 by a method such as CVD. At that time, the air gap AG3 can be formed in the opening K15A.

### Fifth Embodiment

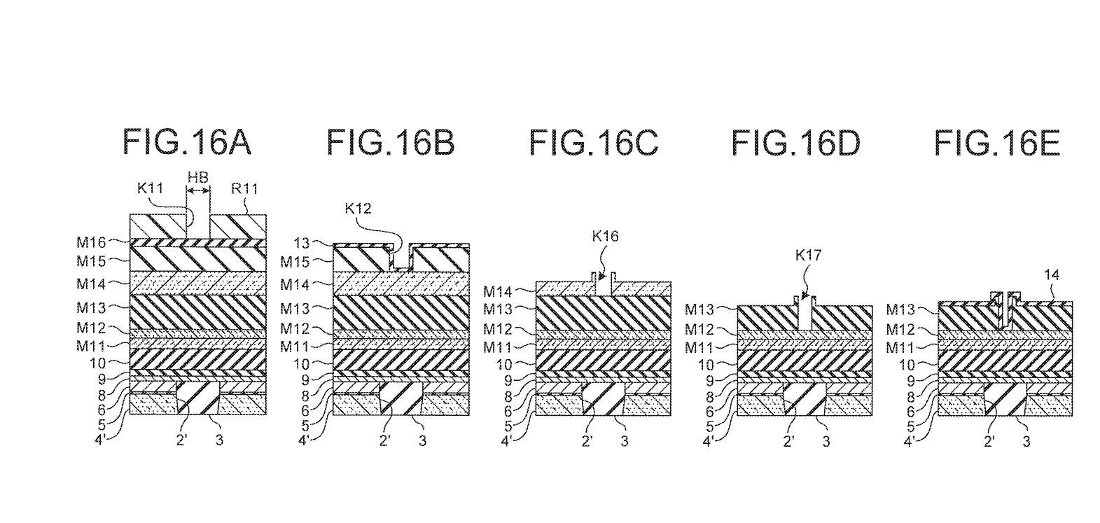

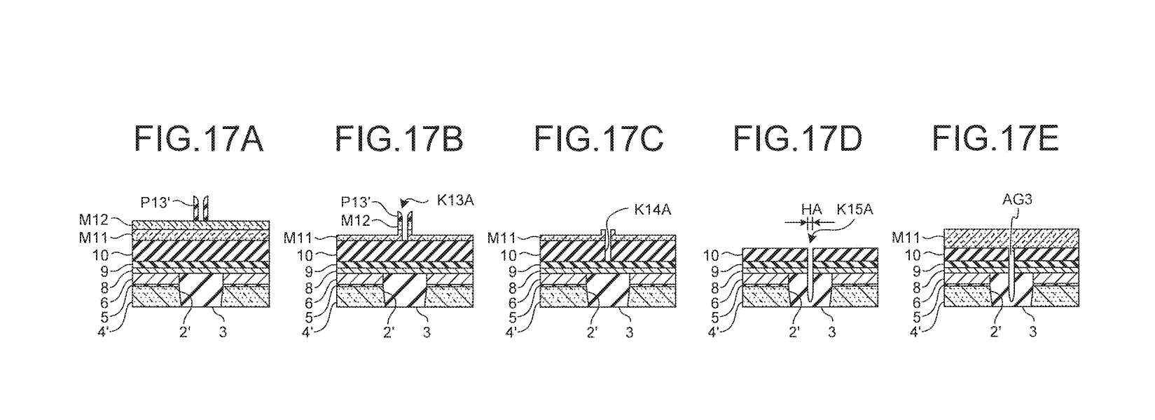

FIGS. 16A to 16E and 17A to 17E are cross-sectional views illustrating a manufacturing method of a non-volatile semiconductor memory device according to a fifth embodiment. In the fifth embodiment, the steps illustrated in FIG. 5A to 5C are implemented using the side wall forming process as another example. The fifth embodiment is configured such that the opening K15B is not formed at the time of formation of the opening K15A illustrated in FIG. 13D without addition of the lithography step illustrated in FIG. 15A.

The steps illustrated in FIGS. 16A and 16B are the same as the steps illustrated in FIGS. 12A and 12B.

As illustrated in FIG. 16C, the spacer film 13 and the hard mask layers M15 and M14 are sequentially etched by a method such as RIE to form an opening K16 in the hard mask layer M14. At that time, the etching rate of the spacer film 13 can be lower than that of the hard mask layer M15. The film thickness of the spacer film 13 can be smaller than that of the hard mask layer M15.

Accordingly, when the hard mask layer M15 is removed from the hard mask layer M14, the spacer film 13 can be left along the outline of the opening K12. In addition, an etching condition can be set to obtain an inverse loading effect at the time of etching of the hard mask layer M14.

Accordingly, the hard mask layer M14 is removed from narrow space in the spacer film 13 left along the outline of the opening K12 to form the opening K16, whereas the hard mask layer M14 can be left on the hard mask layer M13 in a wide region around the spacer film 13. At that time, the film thickness of the hard mask layer M14 can be larger at the edge of the opening K16 than around the opening K16. That is, the hard mask layer M14 can protrude along the outline of the opening K16.

Next, as illustrated in FIG. 16D, the core material layer M13 is etched by a method such as RIE via the opening K16 to form an opening K17 in the core material layer M13. At that time, the film thickness of the core material layer M13 can be larger at the edge of the opening K17 than around the opening K17. That is, the core material layer M13 can protrude along the outline of the opening K17.

Next, as illustrated in FIG. 16E, the side wall layer 14 is formed on the core material layer M13 by a method such as CVD to cover the side walls of the opening K17.

Next, as illustrated in FIG. 17A, the side wall layer 14 and the core material layer M13 are etched by a method such as RIE until the hard mask layer M12 is exposed to form a side wall patterns P13′ on the side walls of the opening K17 and remove the core material layer M13.

Next, as illustrated in FIG. 17B, the hard mask layers M12 and M11 are sequentially etched by a method such as RIE via the side wall patterns P13′ to form the opening K13A in the hard mask layers M12 and M11. At that time, an etching condition can be set to obtain an inverse loading effect.

Accordingly, the hard mask layer M11 is removed from narrow space between the side wall patterns P13′ to form the opening K13A, whereas the hard mask layer M11 can be left on the hard mask layer 10 in a wide region around the side wall patterns P13′.

Next, as illustrated in FIG. 17C, the hard mask layer 10 is etched by a method such as RIE via the opening K13A to form the opening K14A in the hard mask layer 10.

Next, as illustrated in FIG. 17D, the cap insulation film 9 and the control gate electrode 8 are sequentially etched by a method such as RIE via the opening K14A to form the opening K15A in the cap insulation film 9 and the control gate electrode 8.

Next, as illustrated in FIG. 17E, the cover insulation film 11 is formed on the hard mask layer 10 by a method such as CVD. At that time, the air gap AG3 can be formed in the opening K15A.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a non-volatile semiconductor memory device in which memory cells are arranged in a cell array region in a row direction and a column direction, comprising:
forming a conductive layer in the cell array region and a peripheral region;
patterning the conductive layer based on a first mask pattern formed by first lithography to form word lines extending in the cell array region in the row direction and form a slit in the conductive layer in the peripheral region;
forming a first insulation film on the conductive layer to cover the word lines such that a first air gap is generated between the word lines and cover the slit; and
patterning the conductive layer based on a second mask pattern formed by second lithography to form select gate lines extending in the cell array region in the row direction and separate the conductive layer in the peripheral region in the column direction to form gate electrodes divided by the slit in the row direction in the peripheral region.

2. The manufacturing method of a non-volatile semiconductor memory device of claim 1, wherein
the forming the slit in the conductive layer in the peripheral region includes:
forming sequentially a first mask layer, a core material layer, a second mask layer, and a third mask layer on the conductive layer;
forming a first opening in the third mask layer;
forming a spacer film on the third mask layer to cover side walls of the first opening;
etching the second mask layer via the spacer film to form a third mask pattern;
etching the core material layer via the third mask pattern to form a core material pattern on the first mask layer;
forming side wall patterns on the side walls of the core material pattern;
removing the core material pattern between the side wall patterns;
under an etching condition for obtaining an inverse loading effect, forming a second opening in the first mask layer through a space between the side wall patterns while leaving the first mask layer around the side wall patterns on the conductive layer; and
etching the conductive layer through the second opening.

3. The manufacturing method of a non-volatile semiconductor memory device of claim 1, wherein
the forming the slit on the conductive layer in the peripheral region includes:
forming sequentially a first mask layer, a core material layer, a second mask layer, and a third mask layer on the conductive layer;
forming a first opening in the third mask layer;
forming a spacer film on the third mask layer to cover side walls of the first opening;
etching the second mask layer via the spacer film to form a third mask pattern;
etching the core material layer via the third mask pattern to form a core material pattern on the first mask layer;
forming a side wall pattern on side walls of the core material pattern;
under an etching condition for obtaining an inverse loading effect, forming a second opening in the first mask layer through a space between the side wall patterns between which the core material pattern is not formed while leaving the first mask layer on the conductive layer around the core material pattern and the side wall pattern; and
etching the conductive layer through the second opening.

4. The manufacturing method of a non-volatile semiconductor memory device of claim 1, wherein
the forming the slit in the conductive layer in the peripheral region includes:
forming sequentially a first mask layer, a second mask layer, a third mask layer, and a fourth mask layer on the conductive layer;
forming a first opening in the fourth mask layer;
forming a spacer film on the fourth mask layer to cover side walls of the first opening;
etching the third mask layer via the spacer film under an etching condition for obtaining an inverse loading effect to form a second opening with a large film thickness of an edge of the second opening;
etching the second mask layer via the second opening to form a third opening with a large film thickness of an edge of the third opening;
forming side wall patterns on side walls of the third opening;
under an etching condition for obtaining an inverse loading effect, forming a fourth opening in the first mask layer through a space between the side wall patterns while leaving the first mask layer on the conductive layer around the side wall patterns; and
etching the conductive layer through the fourth opening.

5. The manufacturing method of a non-volatile semiconductor memory device of claim 1, wherein a sense amplifier circuit connected to the memory cells is formed in the peripheral region.

6. The manufacturing method of a non-volatile semiconductor memory device of claim 1, wherein
the memory cell includes:
a tunnel insulation film provided on a first active region;
a floating gate electrode provided on the tunnel insulation film;
an inter-electrode insulation film provided on the floating gate electrode; and
a control gate electrode provided on the inter-electrode insulation film, wherein
the gate electrodes of the peripheral circuit are formed from the floating gate electrode and the control gate electrode provided on a second active region, and the inter-electrode insulation film is removed from the gate electrodes of the peripheral circuit.

7. The manufacturing method of a non-volatile semiconductor memory device of claim 6, wherein
the non-volatile semiconductor memory device includes:
a first trench that divides the first active region; and
a second trench that divides the second active region, and
the gate electrodes of the peripheral circuit include fringe portions extending over the second trench.

8. The manufacturing method of a non-volatile semiconductor memory device of claim 7, wherein the floating gate electrode of the gate electrodes of the peripheral circuit is aligned at an edge with the second trench, and the control gate electrode of the gate electrodes of the peripheral circuit extends over the second trench.

9. The manufacturing method of a non-volatile semiconductor memory device of claim 7, wherein the non-volatile semiconductor memory device includes contacts that extend over the fringe portions and are connected to the gate electrodes.

10. The manufacturing method of a non-volatile semiconductor memory device of claim 7, wherein the non-volatile semiconductor memory device includes a second insulation film embedded in the first trench and the second trench.

11. A non-volatile semiconductor memory device, comprising:
a memory cell array in which memory cells are arranged in a row direction and a column direction and word lines are arranged in the row direction,
first air gaps provided between the word lines;
a peripheral circuit provided around the memory cell array;
second air gaps provided between gate electrodes of the peripheral circuit; and
a first insulation film that is provided on the word lines and the gate electrodes, and is in contact with the upper ends of the first air gaps and the upper ends of the second air gaps.

12. The non-volatile semiconductor memory device of claim 11, wherein
the memory cells are connected in serial in the column direction to form an NAND string, a first select transistor is connected to a first end of the NAND string, and a second select transistor is connected to a second end of the NAND string.

13. The non-volatile semiconductor memory device of claim 12, wherein the peripheral circuit is a sense amplifier circuit connected to the memory cell array.

14. The non-volatile semiconductor memory device of claim 12, wherein
the memory cell includes:
a tunnel insulation film provided on a first active region;
a floating gate electrode provided on the tunnel insulation film;
an inter-electrode insulation film provided on the floating gate electrode; and
a control gate electrode provided on the inter-electrode insulation film, wherein
the gate electrodes of the peripheral circuit are formed from the floating gate electrode and the control gate electrode provided on a second active region, and the inter-electrode insulation film is removed from the gate electrodes.

15. The non-volatile semiconductor memory device of claim 14, comprising:
a first trench that divides the first active region; and
a second trench that divides the second active region, and
the gate electrodes of the peripheral circuit include fringe portions extending over the second trench.

16. The non-volatile semiconductor memory device of claim 15, wherein the floating gate electrode of the gate electrodes of the peripheral circuit is aligned at an edge with the second trench, and the control gate electrode of the gate electrodes of the peripheral circuit extends over the second trench.

17. The non-volatile semiconductor memory device of claim 15, comprising contacts that extend over the fringe portions and are connected to the gate electrodes.

18. The non-volatile semiconductor memory device of claim 15, wherein
the gate electrodes of the peripheral circuit include a first gate electrode and a second gate electrode adjacent in the column direction, and
the second air gaps are provided between a fringe portion of the first gate electrode and a fringe portion of the second gate electrode.

19. The non-volatile semiconductor memory device of claim 18, comprising a second insulation film embedded in the first trench and the second trench.

20. The non-volatile semiconductor memory device of claim 19, wherein the second air gaps eat into the second insulation film.
